(19) United States
(12) Patent Application Publication
(10) Pub. No.: US 2008/0232451 A1
(43) Pub. Date: Sep. 25, 2008

(54) METHOD AND APPARATUS FOR EQUALIZATION OF FAST CHANGING CHANNELS IN A TDS-OFDM SYSTEM

(75) Inventor: Qin Liu, FREMONT, CA (US)

Correspondence Address: FRANKLIN (LIN) YANG, 91 CANTERBURY GATE, LYNBROOK, NY, 11563, US

(73) Assignee: LEGEND SILICON CORP., FREMONT, CA (US)

(21) Appl. No.: 11/687,682

(22) Filed: Mar. 19, 2007

(51) Int. Cl. H04B 3/04; H03H 7/40; H03K 5/159

(52) U.S. Cl. 375/232; 375/E01.002

(57) ABSTRACT

A method for channel equalization is provided. The method comprises the steps of: subdividing a received symbol portion into segments wherein each segment is associated with a known, segmented channel characteristic among a set of segmented, known channel characteristics spanning the received symbol.

### FIELD OF THE INVENTION

The present invention relates generally to equalization of OFDM systems, more specifically the present invention relates to equalization of OFDM systems under fast fading channels or high Doppler situations.

### BACKGROUND

Block-based OFDM systems assume that a channel is invariant during one symbol interval. Otherwise, a loss of orthogonality occurs and performance degrades. In order to improve the performance under time-varying channels, it is known to use antenna diversity, or ICI cancellation. For antenna diversity, the undesirables include higher cost for additional antennas, and footprint limitations in such devices as a mini-hand held that does not have additional space for additional antenna. For ICI cancellation, it has performance limitations and is complex in nature. Therefore, an improved equalization scheme which is simple to implement and has significant better performance is desired.

### SUMMARY OF THE INVENTION

A method for channel equalization comprising the steps of: subdividing a received symbol portion into segments wherein each segment is associated with a known, segmented channel characteristic among a set of segmented, known channel characteristics spanning the received symbol.

In a TDS-OFDM system, a method for channel equalization comprising the steps of: subdividing a received symbol portion into segments wherein each segment is associated with a known, segmented channel characteristic among a set of segmented, known channel characteristics spanning the received symbol.

In a TDS-OFDM system with PN sequence serving as the guard intervals, a method for channel equalization comprising the steps of: subdividing a received symbol portion into segments wherein each segment is associated with a known, segmented channel characteristic among a set of segmented, known channel characteristics spanning the received symbol.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a TDS-OFDM frame composition in accordance with some embodiments of the invention.

FIG. 2 is an example of a receiver in accordance with some embodiments of the invention.

FIG. 3 is an example of a received frame in accordance with some embodiments of the invention.

FIG. 4 is an example of subdividing a section into segments in accordance with some embodiments of the invention.

FIG. 5 is a flowchart in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to subdividing a received symbol portion into segments wherein each segment is associated with a known, segmented channel characteristic. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of subdividing a received symbol portion into segments wherein each segment is associated with a known, segmented channel characteristic described herein. The non-processor circuits may include, but are not limited to, a radio receiver, a radio transmitter, signal drivers, clock circuits, power source circuits, and user input devices. As such, these functions may be interpreted as steps of a method to perform subdividing a received symbol portion into segments wherein each segment is associated with a known, segmented channel characteristic. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

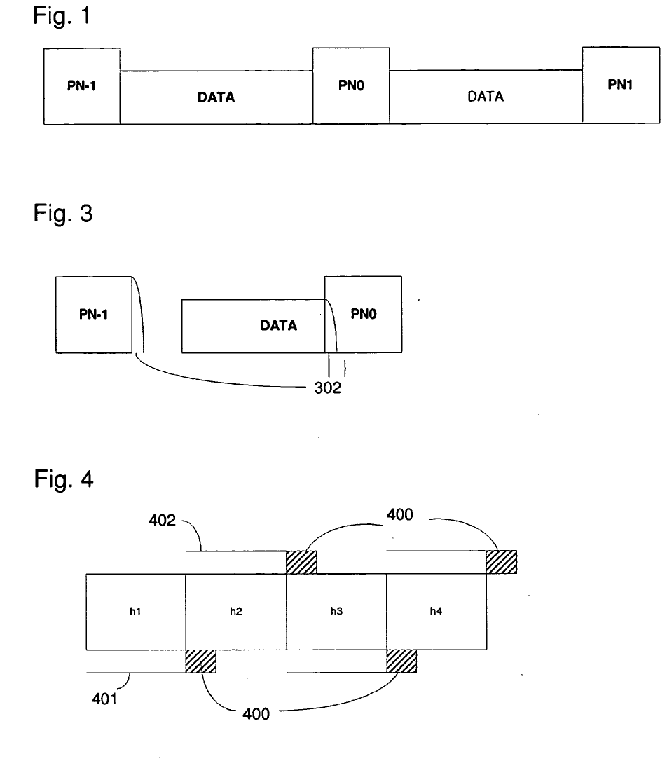

Referring to FIGS. 1-5, an example of a segmented equalization system is shown. In FIG. 1, a frame structure of TDS-OFDM is depicted. One frame consists of PN followed by data. The frame is positioned sequentially within a frame among a multiplicity of frames. As can be appreciated, PNs are disposed between the OFDM symbols. It is noted that the present invention contemplates using the PN sequence disclosed in U.S. Pat. No. 7,072,289 to Yang et al which is hereby incorporated herein by reference.

In FIG. 2, a receiver 10 for implementing a LDPC based TDS-OFDM communication system is shown. Receiver 10 performs synchronization, channel estimation, equalization, decoding. In other words, FIG. 2 is a block diagram illustrating the functional blocks of an LDPC based TDS-OFDM receiver 10. Demodulation herein follows the principles of TDS-OFDM modulation scheme. Error correction mechanism is based on LDPC. The primary objectives of the receiver 10 is to determine from a noise-perturbed system, which of the finite set of waveforms have been sent by a transmitter and using an assortment of signal processing techniques to reproduce the finite set of discrete messages sent by the transmitter.

The block diagram of FIG. 2 illustrates the signals and key processing steps of the receiver 10. It is assumed that the input signal 12 to the receiver 10 is a down-converted digital signal. The output signal 14 of receiver 10 is a MPEG-2 transport stream. More specifically, the RF (radio frequency) input signals 16 are received by an RF tuner 18 where the RF input signals are converted to low-IF (intermediate frequency) or zero-IF signals 12. The low-IF or zero-IF signals 12 are provided to the receiver 10 as analog signals or as digital signals (through an optional analog-to-digital converter 20).

In the receiver 10, the IF signals are converted to base-band signals 22. TDS-OFDM demodulation is then performed according to the parameters of the LDPC (low-density parity-check) based TDS-OFDM modulation scheme. The output of the channel estimation 24 and correlation block 26 is sent to a time de-interleaver 28 and then to the forward error correction (FEC) block. The output signal 14 of the receiver 10 is a parallel or serial MPEG-2 transport stream including valid data, synchronization and clock signals. The configuration parameters of the receiver 10 can be detected or automatically programmed, or manually set. The main configurable parameters for the receiver 10 include: (1) Sub carrier modulation type including: QPSK, 16 QAM, 64 QAM; (2) FEC rate including: 0.4, 0.6 and 0.8; (3) Guard interval having: 420 or 945 symbols; (4) Time de-interleaver mode including three modes respectively having: 0, 240 or 720 symbols; (5) Control frames detection; and (6) Channel bandwidth including: 6, 7, or 8 MHz.

The functional blocks of the receiver 10 are described as follows.

Automatic gain control (AGC) block 30 compares the input digitized signal strength with a reference. The difference is filtered and the filter value 32 is used to control the gain of the amplifier 18. The analog signal provided by the tuner 12 is sampled by an ADC 20. The resulting signal is centered at a lower IF. For example, sampling a 36 MHz IF signal at 30.4 MHz results in the signal centered at 5.6 MHz. The IF to Baseband block 22 converts the lower IF signal to a complex signal in the baseband. The ADC 20 uses a fixed sampling rate. Conversion from this fixed sampling rate to the OFDM sample rate is achieved using the interpolator in block 22. The timing recovery block 32 computes the timing error and filters the error to drive a Numerically Controlled Oscillator (not shown) that controls the sample timing correction applied in the interpolator of the sample rate converter.

There can be frequency offsets in the input signal 12. The automatic frequency control block 34 calculates the offsets and adjusts the IF to baseband reference IF frequency. To improve capture range and tracking performance, frequency control is done in two stages: a coarse stage and a fine stage. Since the transmitted signal is square root raised cosine filtered, the received signal will be applied with the same function. It is known that signals in a TDS-OFDM system include a PN sequence preceding the IDFT symbol. By correlating the locally generated PN with the incoming signal, it is easy to find the correlation peak (so the frame start can be determined) and other synchronization information such as frequency offset and timing error. Channel time domain response is based on the signal correlation previously obtained. Frequency response is taking the FFT of the time domain response.

In TDS-OFDM, a PN sequence replaces the traditional cyclic prefix. It is thus necessary to remove the PN sequence and restore the channel spreaded OFDM symbol. Block 36 reconstructs the conventional OFDM symbol that can be one-tap equalized. The FFT block 38 performs a fixed point FFT such as a 3780 point FFT. Channel equalization 40 is carried out from the FFT 38 transformed data based on the frequency response of the channel. De-rotated data and the channel state information are sent to FEC for further processing.

In the TDS-OFDM receiver 10, the time-deinterleaver 28 is used to increase the resilience to spurious noise. The time-deinterleaver 28 is a convolutional de-interleaver which needs a memory with size B*(B−1)*M/2, where B is the number of the branch, and M is the depth. For the TDS-OFDM receiver 10 of the present embodiment, there are three modes of time-deinterleavering. For mode 1 B=52, M=48, mode 2 B=52, M=240, and for mode 3, B=52, M=720.

The LDPC decoder 42 is a soft-decision iterative decoder for decoding, for example, a Quasi-Cyclic Low Density Parity Check (QC-LDPC) code provided by a transmitter (not shown). LDPC decoder 42 is configured to decode at 3 different rates (i.e. rate 0.4, rate 0.6 and rate 0.8) of QC_LDPC codes by sharing the same piece of hardware. The iteration process is either stopped when it reaches the specified maximum iteration number (full iteration), or when the detected error is free during error detecting and correcting process (partial iteration).

The TDS-OFDM modulation/demodulation system is a multi-rated system based on multiple modulation schemes (e.g. QPSK, 16 QAM, 64 QAM), and multiple coding rates (0.4, 0.6, and 0.8), where QPSK stands for Quad Phase Shift Keying and QAM stands for Quadrature Amplitude Modulation. The output of BCH decoder 46 is bit by bit. According to different modulation schemes and coding rates, the rate conversion block 44 combines the bit output of BCH decoder 46 to bytes, and adjusts the speed of byte output clock to make the receiver 10's MPEG frames outputs evenly distributed during the whole demodulation/decoding process.

The BCH decoder 46 is designed to decode codes such as BCH (762, 752) code, which is the shortened binary BCH code of BCH (1023, 1013). The generator polynomial is x̂10+x̂3+1.

Since the data in the transmitter has been randomized using a pseudo-random (PN) sequence before BCH encoder (not shown), the error corrected data by the LDPC/BCH decoder 46 must be de-randomized. The PN sequence is generated by the polynomial 1+x¹⁴+x¹⁵, with initial condition of 100101010000000. The de-scrambler/de-randomizer 48 will be reset to the initial condition for every signal frame. Otherwise, de-scrambler/de-randomizer 48 will be free running until reset again. The least significant 8-bit will be XORed with the input byte stream.

The data flow through the various blocks of the modulator is as follows. The received RF information 16 is processed by a digital terrestrial tuner 18 which picks the frequency bandwidth of choice to be demodulated and then downconverts the signal 16 to a baseband or low-intermediate frequency. This downconverted information 12 is then converted to the Digital domain through an analog-to-digital data converter 20.

The baseband signal after processing by a sample rate converter 50 is converted to symbols. The PN information found in the guard interval is extracted and correlated with a local PN generator to find the time domain impulse response. The FFT of the time domain impulse response gives the estimated channel response. The correlation 26 is also used for the timing recovery 32 and the frequency estimation and correction of the received signal. The OFDM symbol information in the received data is extracted and passed through a 3780 FFT 38 to obtain the symbol information back in the frequency domain. Using the estimated channel estimation previously obtained, the OFDM symbol is equalized and passed to the FEC decoder.

At the FEC decoder, the time-deinterleaver block 28 performs a deconvolution of the transmitted symbol sequence and passes the 3780 blocks to the inner LDPC decoder 42. The LDPC decoder 42 and BCH decoders 46 which run in a serial manner take in exactly 3780 symbols, remove the 36 TPS symbols and process the remaining 3744 symbols and recover the transmitted transport stream information. The rate conversion 44 adjusts the output data rate and the de-randomizer 48 reconstructs the transmitted stream information. An external memory 52 coupled to the receiver 10 provides memory thereto on a predetermined or as needed basis.

In FIG. 3, a received symbol taking a time lag, delta (δ), 302 into consideration and having PN as guard intervals is shown. The delta is a reflection of the inaccuracies or the quality of a channel, wherein the received symbol was subjected to. For computational purposes, the length of delta should be less than the length of the PN sequence. Otherwise inter-symbol interference occurs. It is desirable to process (i.e. equalize) the data so that channel effect is minimized and delta 302 disappears. By way of example, assuming no data is transmitted (i.e. the frames are empty or set to zeros), the PNs still has the delta effect. Using the method of the present invention, delta 302 disappears.

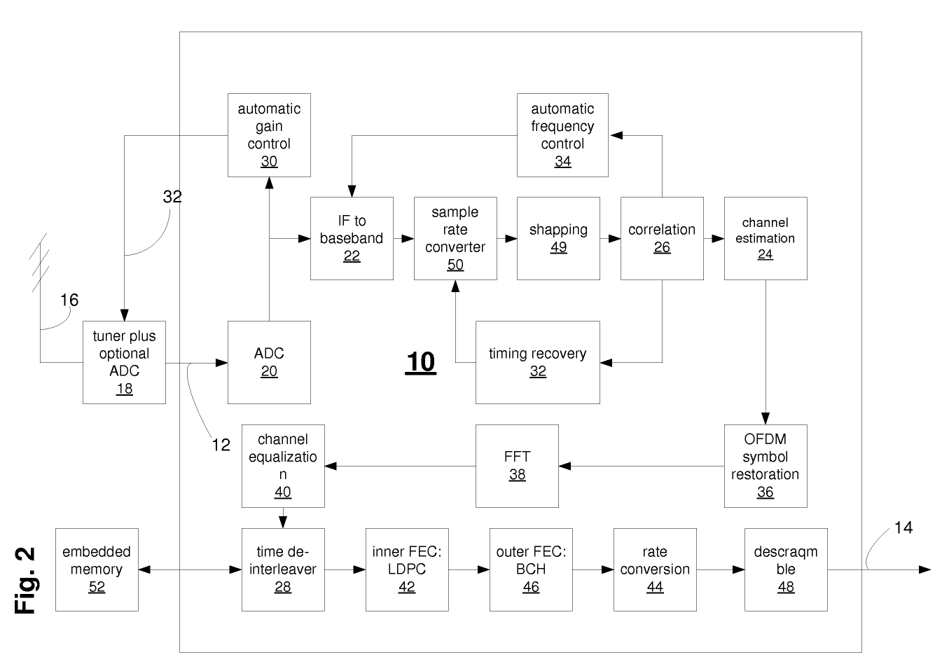

In FIG. 4, delta 400 is used as the overlap length for a 4 segmented scheme. For example a length of 3780 symbol is segmented into four equal segments. As can be seen, each segment is 945 long. Delta 400 is chosen at 200 long. The resultant first overlap length 401 is 1045. Similarly, the second overlap length 402 and the fourth overlap length are also 1045. The third and fourth overlap lengths have similar values. Delta 400 that is used as the overlap is not limited to a 4 segmented scheme. Other positive integers such as 2 is contemplated by the present invention as well. In other words, the data part is divided into several (n) portions (depending on channel profile, e.g, 945+200 overlapped portions). Then the (FFT, IFFT size should be larger than 945+200. Taking only the first 945 symbols and concatenate them and than doing FFT3780 will result in the equalized result. The choice in value of delta 400 depends on channel length. The segment length should be M times of delta, with M defined as about the ratio of 945/200. M is chosen as a real number greater than or equal to 3. For example, for a segment that is 945 in length, delta=200.

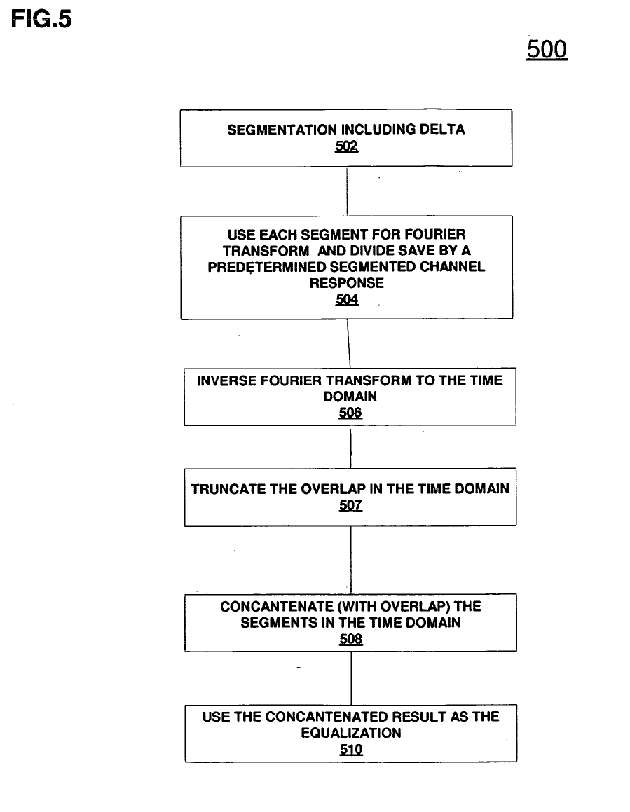

In FIG. 5, a flowchart 500 of the present invention is shown. Segmentation is done over a symbol length, and including an additional length delta (Step 502). Use each segment for a separate Fourier transform and divide same by a predetermined segmented channel response that is reflective of that particular segment only (Step 504). In other words, F(yₙ)/F(hₙ) wherein n is a predetermined positive integer greater than or equal to two (2) such as 2 or 4. Where hₙ is a series of segmented channel response and is a known quantity. Inverse Fourier transform to the time domain (step 506). In other words, for section one F⁻¹[F(y₁)/F(h₁)].

After all the segments go through the same process, delta length is truncated (Step 507) and concantenate delta 400 the segments in the time domain (step 508). Use the concantenated result as the equalized symbol estimate (step 510).

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued. Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. A method for channel equalization comprising the steps of:
subdividing a received symbol portion into segments wherein each segment is associated with a known, segmented channel characteristic among a set of segmented, known channel characteristics spanning the received symbol.

2. The method of claim 1 further comprising the step of transforming each segment and performing an operation upon the transformed segment using an associated segmented channel characteristic to achieve an operated result.

3. The method of claim 2 further comprising the step of reverse transforming the operated result.

4. The method of claim 1 further comprising the step of truncating each segment to their respective original length.

5. The method of claim 1 further comprising the step of concatenating all the segmented, transformed segments in time domain.

6. The method of claim 1, wherein at least one pseudo noise (PN) sequence is used as at least one guard interval between symbols.

7. The method of claim 1, wherein the known channel characteristics comprise channel time domain response.
